(19) United States
(12) Patent Application Publication
(10) Pub. No.: US 2026/0351531 A1
(43) Pub. Date: Nov. 5, 2026

(54) PLASMA CHAMBER AND WAFER ETCHING METHOD USING PLASMA CHAMBER

(71) Applicant: NYSE STAR CORP., Country of New Castle, DE (US)

(72) Inventor: Nam Hun KIM, Yeoju-si, Gyeonggi-do (KR)

(73) Assignee: NYSE STAR CORP., Country of New Castle, DE (US)

(21) Appl. No.: 19/117,972

(22) PCT Filed: Aug. 24, 2023
(86) PCT No.: PCT/KR2023/012525

§ 371 Date: Apr. 3, 2025

(30) Foreign Application Priority Data
Oct. 21, 2022 (KR) 10-2022-0136836

(51) Int. Cl. H01J 37/32; H10P 50/24

(52) U.S. Cl. CPC H01J 37/32816; H01J 37/32449; H10P 50/24; H01J 2237/182; H01J 2237/334

(57) ABSTRACT

The present invention relates to a plasma chamber and a wafer etching method using the plasma chamber, wherein the plasma chamber includes: a housing configured to have a reaction space therein, in order to etch a wafer through plasma; a base plate provided inside the housing and configured to allow the wafer to be seated thereon; and a pressure adjustment unit configured to adjust a pressure inside the housing, wherein the pressure adjustment unit is configured to adjust the pressure inside the housing from 50 to 500 mTorr, and the wafer etching method using the plasma chamber of the present invention includes: a pressure adjustment step of adjusting the pressure inside the housing; and a source power adjustment step of adjusting a plasma source.

### TECHNICAL FIELD

The present invention relates to a plasma chamber and a wafer etching method using the plasma chamber, and more specifically, to the plasma chamber and the wafer etching method using the plasma chamber that can improve selectivity while maintaining a high etch rate.

### BACKGROUND ART

In general, in a process of manufacturing a semiconductor, it is very important to ensure uniformity, and the uniformity of the semiconductor may be secured or controlled in an etching process during the manufacturing process of the semiconductor.

The etching process of the semiconductor may be progressed inside a plasma chamber. The plasma chamber forms plasma in a reaction space therein, and performs the etching process of the semiconductor using the plasma.

A plasma source for forming the plasma is provided to an upper part of the plasma chamber, and typical examples of the plasma source include a capacitively coupled plasma (CCP) source and an inductively coupled plasma (ICP) source.

The capacitively coupled plasma (CCP) source utilizes an electric field and typically allows etching to occur at slightly higher pressures than the inductively coupled plasma (ICP). The capacitively coupled plasma (CCP) source is known to have a slow etch rate, but have excellent selectivity characteristic and process reproducibility.

However, the capacitively coupled plasma (CCP) source is characterized by plasma density non-uniformity, where a plasma density at a center of a wafer is relatively higher than a plasma density at an edge of the wafer. In addition, the overall plasma density is low, so that a high radio frequency (RF) power should be applied to increase the plasma density.

The inductively coupled plasma (ICP) utilizes an inductive magnetic field, and has an advantage of the higher overall plasma density compared to the capacitively coupled plasma (CCP) source. The inductively coupled plasma (ICP) can increase the etch rate at a pressure lower than that of the capacitively coupled plasma (CCP) source, but it also has the problem that the plasma density at the center of the wafer is relatively high compared to the plasma density at the edge of the wafer, and although the etch rate is high, the selectivity is low and the process reproducibility is poor.

As such, conventional plasma sources such as the capacitively coupled plasma (CCP) and the inductively coupled plasma (ICP) have a problem that it is difficult to simultaneously increase the etch rate and the selectivity, and the etch rate and the selectivity have been recognized as a trade-off relationship.

### DISCLOSURE OF INVENTION

### Technical Problem

The present invention is implemented to solve problems described above, and more particularly, relates to a plasma chamber and a wafer etching method using the plasma chamber that can improve selectivity while maintaining a high etch rate.

### Solution to Problem

To solve the above problems, the present invention may provide a plasma chamber configured to form plasma, the plasma chamber comprising: a housing configured to have a reaction space therein, in order to etch a wafer through the plasma; a base plate provided inside the housing and configured to allow the wafer to be seated thereon; and a pressure adjustment unit configured to adjust a pressure inside the housing, wherein the pressure adjustment unit is configured to adjust the pressure inside the housing from 50 to 500 mTorr.

The plasma chamber of the present invention for solving the above problems may further comprise a plasma source provided on an upper part of the housing and configured to form the plasma inside the housing, and a source power of the plasma source may be from 500 to 3000 W.

The pressure adjustment unit of the plasma chamber of the present invention for solving the above problems may be configured to adjust the pressure inside the housing to a pressure equal to or greater than a resonance pressure, at which a driving frequency of the plasma source and a collision frequency between particles inside the housing are equalized.

Etching gas of the plasma chamber of the present invention for solving the above problems may be supplied inside the housing and the etching gas supplied into the housing may be discharged outside the housing after reaction, and a time period for which the etching gas remains inside the housing may be from 1 second to 4 seconds.

A density of the plasma formed in the reaction space of the housing of the plasma chamber of the present invention for solving the above problems may be from 2E11 to 5E11 per cubic centimeter (cm−³).

The plasma chamber of the present invention for solving the above problems may further comprise a bias RF source connected to the base plate and configured to apply a bias to the base plate, and a bias power of the bias RF source may be from 500 to 5000 W.

The plasma formed in the reaction space of the housing of the plasma chamber of the present invention for solving the above problems may include ions and radicals, and the wafer may be etched by synergy effect of the ions and the radicals.

To solve the above problems, the present invention may provide a wafer etching method using a plasma chamber, which includes a housing configured to have a reaction space therein in order to etch a wafer through plasma, a base plate provided inside the housing and configured to allow the wafer to be seated thereon, a pressure adjustment unit configured to adjust a pressure inside the housing, and a plasma source provided on an upper part of the housing and configured to form the plasma inside the housing, the method comprising: a pressure adjustment step of adjusting the pressure inside the housing to be 50to 500 mTorr though the pressure adjustment unit; and a source power adjustment step of adjusting a source power of the plasma source to be 500 to 3000 W through the plasma source.

In the pressure adjustment step of the wafer etching method using the plasma chamber of the present invention for solving the above problems, the pressure inside the housing may be adjusted to a pressure equal to or greater than a resonance pressure, at which a driving frequency of the plasma source and a collision frequency between particles inside the housing are equalized, through the pressure adjustment unit.

Etching gas of the wafer etching method using the plasma chamber of the present invention for solving the above problems may be supplied inside the housing and the etching gas supplied into the housing may be discharged outside the housing after reaction, and a time period for which the etching gas remains inside the housing may be from 1 second to 4 seconds.

A density of the plasma formed in the reaction space of the housing of the wafer etching method using the plasma chamber of the present invention for solving the above problems may be from 2E11 to 5E11 per cubic centimeter (cm⁻³).

The plasma chamber of the wafer etching method using the plasma chamber of the present invention for solving the above problems may include a bias RF source connected to the base plate and configured to apply a bias to the base plate, and the wafer etching method may further comprise a bias power adjustment step of adjusting a bias power of the bias RF source to be 500 to 5000 W through the bias RF source.

The plasma formed in the reaction space of the housing of the wafer etching method using the plasma chamber of the present invention for solving the above problems may include ions and radicals, and the wafer may be etched by synergy effect of the ions and the radicals.

### Advantageous Effects of Invention

The present invention relates to a plasma chamber and a wafer etching method using the plasma chamber, which has an advantage that by forming a pressure inside the plasma chamber to be relatively high compared to a conventional chamber, the etching of the wafer can be conducted by utilizing ions and radicals simultaneously, thereby improving PR selectivity while maintaining a high etch rate.

Additionally, the present invention has an advantage that the high etch rate and the high PR selectivity can be obtained while using a lower power in a plasma source and a biased RF source, compared to a conventional chamber.

### BRIEF DESCRIPTION OF DRAWINGS

FIG. 1 is a drawing illustrating ions and radicals for etching a wafer.

FIG. 2 is a drawing illustrating a plasma chamber according to an embodiment of the present invention.

FIG. 3 is a drawing illustrating a wafer etching method using the plasma chamber according to the embodiment of the present invention.

FIG. 4 is a drawing illustrating a process region for utilizing the ions and the radicals according to the embodiment of the present invention.

FIG. 5 is a drawing illustrating a change in a etch rate according to a bias power and a pressure, when the etching of the wafer is performed using the ions.

FIG. 6 is a diagram illustrating a change in the etch rate according to the bias power and the pressure, when the etching of the wafer is performed using the ions and the radicals according to an embodiment of the present invention.

### BEST MODE FOR CARRYING OUT THE INVENTION

The present description explains principles of the present invention and discloses embodiments, in order to clarify the scope of the present invention and to enable one of ordinary skill in the art to practice the present invention. The disclosed embodiments may be implemented in various forms.

Expressions such as “comprise,” “may comprise” and the like as may be used in various embodiments of the present invention refer to the presence of the corresponding feature, operation, component and the like as disclosed and are not intended to limit one or more additional features, operations, components, and the like. Further, in various embodiments of the present invention, the terms “comprise,” “include,” “has” and the like are intended to designate the presence of the features, numbers, steps, operations, elements, components, parts, or combinations thereof as described in the specification, and are not intended to preclude the possibility of the presence or addition of one or more other features, numbers, steps, operations, elements, parts, or combinations thereof.

It should be understood that when a certain component is referred to as being “connected to” or “coupled to” another component, this component may be directly connected to or coupled to another component, or any intervening components may be present between the components. In contrast, when a certain component is referred to as being “directly connected to” or “directly coupled to” another component, there are no intervening components present.

Although the terms “first,” “second,” etc., may be used herein to describe various components, these components should not be limited by these terms. These terms are only used to distinguish one component from another component.

The present invention relates to a plasma chamber and a wafer etching method using the plasma chamber, which can improve selectivity while maintaining a high etch rate.

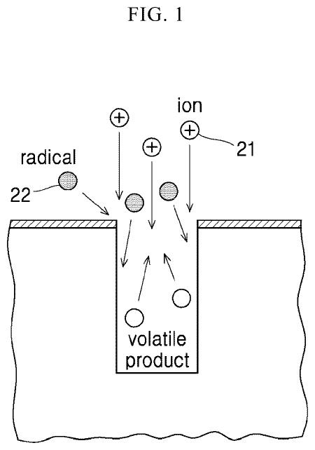

Referring to FIG. 1, plasma is largely composed of electrons, ions 21 and radicals 22. In a conventional method for etching a wafer with the plasma, a dominant species is formed as either the ions or the radicals during a plasma etching process.

Specifically, in the conventional method for etching the wafer with the plasma, metal etch utilizes mainly the radicals, and oxide etch utilizes mainly the ions.

The plasma chamber and the wafer etching method using the plasma chamber according to an embodiment of the present invention may utilize both the ions 21 and the radicals 22 simultaneously, rather than form the dominant species as either the ions or the radicals, during the plasma etching process.

In other words, the plasma chamber and the wafer etching method using the plasma chamber according to the embodiment of the present invention utilize a process region in which the ions 21 and the radicals 22 act together to produce synergy effect, instead of an ion-dominated reaction or a radical-dominated reaction, during the plasma etching process.

More specifically, the plasma chamber and the wafer etching method using the plasma chamber according to the embodiment of the present invention are capable of improving selectivity while maintaining a high etch rate, through the synergy effect of the ions and the radicals along with resonance phenomenon which is caused by collision between the particles and an applied source frequency.

The plasma chamber and the wafer etching method using the plasma chamber according to the embodiment of the present invention may improve the conventional method using an inductively coupled plasma (ICP) source while solving the problems thereof.

The plasma chamber and the wafer etching method using the plasma chamber according to the embodiment of the present invention may be a synergistic resonance ICP (SRICP) that uses the resonance and the synergy effect.

The plasma chamber and the wafer etching method using the plasma chamber according to the embodiment of the present invention may adjust conditions of the plasma chamber to utilize the ions and the radicals simultaneously.

The plasma chamber and the wafer etching method using the plasma chamber according to the embodiment of the present invention, may adjust a pressure inside the chamber, a source power of a plasma source, a density of plasma inside the chamber, a bias power of a bias RF source, and the like. The plasma chamber and the wafer etching method using the plasma chamber according to the embodiment of the present invention, may utilize the ions and the radicals simultaneously by changing the above conditions in the plasma chamber.

Hereinafter, a preferred embodiment of the present invention will be described in detail with reference to accompanying drawings.

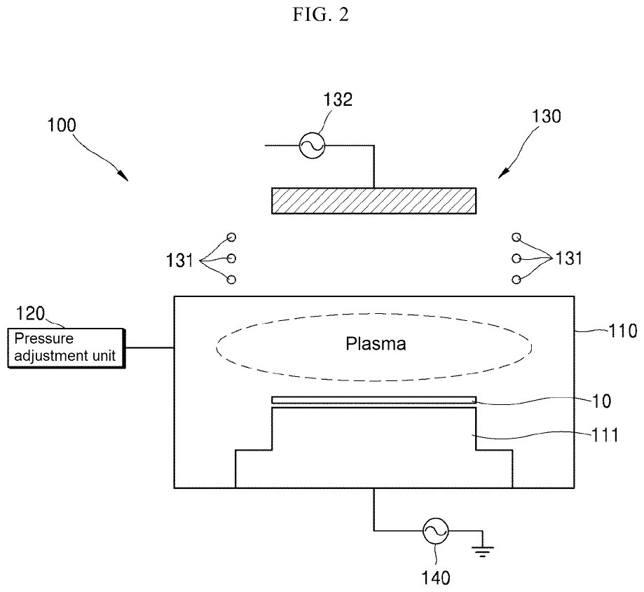

Referring to FIG. 2, a plasma chamber 100 according to the embodiment of the present invention may comprise a housing 110, a base plate 111, and a pressure adjustment unit 120.

The housing 110 is provided with a reaction space in an interior thereof, for etching a wafer 10 via plasma. The housing 110 may be a chamber outer wall of the plasma chamber 100 according to the embodiment of the present invention, and may be provided with a space inside. When the wafer 10 is loaded into the housing 110, the wafer 10 may be etched by the plasma formed inside the housing 110.

The base plate 111 is provided inside the housing 110, and the wafer 10 is seated or rested on the base plate 111. The base plate 111 may be a plate provided inside the housing 110, on which the wafer 10 is mounted.

More specifically, the base plate 111 may be a wafer chuck that supports the wafer 10 while seating the wafer 10 thereon, and once the wafer 10 is seated on the base plate 111, the etching of the wafer 10 may proceed.

The pressure adjustment unit 120 is to adjust or regulate the pressure inside the housing 110. The pressure adjustment unit 120 may be a pressure regulator for regulating the pressure inside the housing 110, and the pressure adjustment unit 120 may be a device comprising various configurations, which can regulate the pressure inside the housing 110.

According to the embodiment of the present invention, the pressure adjustment unit 120 may adjust the pressure inside the housing 110 from 50 to 500 mTorr. As described above, the plasma chamber according to the embodiment of the present invention, may utilize the ions 21 and the radicals 22 simultaneously.

The plasma chamber according to the embodiment of the present invention may adjust the pressure inside the housing 110 from 50 to 500 mTorr via the pressure adjustment unit 120 in order to utilize the ions 21 and the radicals 22 simultaneously.

In the plasma chamber according to the embodiment of the present invention, if the pressure inside the housing 110 is less than 50 mTorr, the synergy effect of utilizing ions 21 and radicals 22 simultaneously becomes difficult to achieve.

More specifically, if the pressure inside the housing 110 is less than 50 mTorr, an ion 21 dominated etching reaction may occur. Furthermore, when both ions 21 and radicals 22 are used simultaneously, there is a risk that the etch rate is reduced if the pressure inside the housing 110 is less than 50 mTorr.

If the pressure inside the housing 110 becomes greater than 500 mTorr, the reaction time may become shorter due to excessive reactions between the particles, and the etch rate may decrease instead.

Therefore, the plasma chamber according to the embodiment of the present invention preferably regulates the pressure inside the housing 110 from 50 to 500 mTorr via the pressure adjustment unit 120.

Further, according to another embodiment of the invention, the pressure inside the housing 110 may be regulated to be 100 to 150 mTorr, 200 to 500 mTorr, 300 to 500 mTorr, via the pressure adjustment unit 120.

The plasma chamber according to the embodiment of the present invention may further comprise a plasma source 130 provided on an upper part of the housing 110 and forming the plasma inside the housing 110.

The plasma source 130 may be configured to form the plasma and may include a coil 131 and an RF power generator 132. According to the embodiment of the present invention, a source power of the plasma source 130 may be adjustable from 500 to 3000 W.

Preferably, the source power formed by the plasma source 130 is greater than 500 W because if the source power formed by the plasma source 130 is less than 500 W, the etch rate decreases.

As described above, the plasma chamber according to the embodiment of the present invention adjusts the pressure inside the housing 110 from 50 to 500 mTorr via the pressure adjustment unit 120, so that the pressure inside the housing 110 may be higher than a pressure of the conventional plasma chamber.

When the source power formed by the plasma source 130 is greater than 3000 W, a plasma density may become excessively high due to the relatively high internal pressure of the housing 110. If the plasma density becomes too high, the reaction time may be shortened due to excessive reactions between the particles, and the etch rate may be reduced instead.

Therefore, the plasma chamber according to the embodiment of the present invention preferably adjusts the source power of the plasma source 130 from 500 to 3000 W. Further, according to another embodiment of the present invention, the source power of the plasma source 130 may be adjusted from 500 to 1500 W.

The pressure adjustment unit 120 of the plasma chamber according to the embodiment of the present invention may adjust the pressure inside the housing 110 to a pressure equal to, or greater than, a resonance pressure.

Here, the resonance pressure may be a pressure at which a driving frequency of the plasma source 130 and a collision frequency between the particles inside the housing 110 are equalized.

For example, when the driving frequency of the plasma source 130 is 13.56 MHz, the resonance pressure at which the driving frequency of the plasma source 130 and the collision frequency between the particles inside the housing 110 are equalized, may be 52 mTorr for Ar gas, and when the driving frequency of the plasma source 130 is 27.12 MHz, the resonance pressure may be 104 mTorr for Ar gas.

The pressure adjustment unit 120 according to the embodiment of the present invention may adjust the pressure inside the housing 110 to the pressure equal to, or greater than, the resonance pressure determined by the driving frequency of the plasma source 130.

According to the embodiment of the present invention, the collision frequency between the particles inside the housing 110 may be determined as the product of the number of particles per unit volume and a rate constant for collision reaction.

The plasma chamber according to the embodiment of the present invention may comprise a collision frequency analysis unit for analyzing the collision frequency between the particles occurring inside the housing 110. With the collision frequency analysis unit, it is possible to derive the resonance pressure at which the collision frequency becomes equal to the driving frequency of the plasma source 130.

According to the embodiment of the present invention, the pressure adjustment unit 120 may receive data on the resonance pressure via the collision frequency analysis unit, which enables the pressure adjustment unit 120 to adjust the pressure inside the housing 110 to the pressure equal to or greater than the resonance pressure.

According to the embodiment of the present invention, the density of the plasma formed in the reaction space of the housing 110 is preferably from 2E11 to 5E11 per cubic centimeter (cm⁻³).

If the density of the plasma formed in the reaction space of the housing 110 is less than 2E11 per cubic centimeter (cm⁻³), the targeted etch rate may not be obtained.

In contrast, if the density of the plasma formed in the reaction space of the housing 110 is greater than 5E11 per cubic centimeter (cm⁻³), the ions 21 and the radicals 22 are separated, and this may adversely affect the selectivity.

In other words, the plasma chamber according to the embodiment of the present invention may form the density of the plasma in the reaction space of the housing 110 to have a range from 2E11 to 5E11 per cubic centimeter (cm⁻³) in order to improve the selectivity while improving the etch rate by simultaneously utilizing the ions 21 and the radicals 22.

The density of the plasma formed in the reaction space of the housing 110 according to the embodiment of the present invention may be adjusted or regulated by the plasma source 130. In particular, by the plasma source 130, it becomes possible to form inside the housing 110 the plasma density suitable for the simultaneous utilization of ions 21 and radicals 22.

Referring to FIG. 2, the plasma chamber 100 according to the embodiment of the present invention may further comprise a bias RF source 140 connected to the base plate 111 and capable of applying a bias to the base plate 111.

The bias RF source 140 may apply the bias to the base plate 111, thereby applying the bias to the plasma during the etching process.

According to the embodiment of the invention, a bias power of the bias RF source 140 is preferably adjusted from 500 to 5000 W. The bias power directly affects the ions 21.

If the bias power of the bias RF source 140 is less than 500 W, the activity of the ion 21 is restricted and the radical 22 is enabled to dominantly act, and thus the synergy effect of the ion 21 and the radical 22 may not be expected.

On the contrary, if the bias power of the bias RF source 140 is greater than 5000 W, the synergy effect of the ions 21 and the radicals 22 may not be expected as the ions become dominantly active.

Consequently, the plasma chamber 100 according to the embodiment of the present invention is required to adjust the bias power of the bias RF source 140 from 500 to 5000 W in order to derive the synergy effect through the ions 21 and the radicals 22.

Inside the housing 110 of the plasma chamber 100 according to the embodiment of the present invention, etching gas for etching the wafer may be supplied. The etching gas supplied into the housing 110 may be discharged out of the housing 110 via a pump or the like after the reaction.

According to the embodiment of the present invention, a time period for which the etching gas remains or stays inside the housing 110 may be from 1 second to 4 seconds. Here, the time period for the etching gas to remain inside the housing 110 may be a time period from a point of time (or a moment) when the etching gas is supplied inside the housing 110 to a point of time when the etching gas is discharged outside the housing 110.

If the time period for the etching gas to reside inside the housing 110 is less than 1 second, a flow of the etching gas is not performed smoothly, and thus the reaction becomes not sufficient.

On the contrary, if the time period for the etching gas to reside inside the housing 110 is greater than 4 seconds, polymerization of byproduct may cause random accumulation of the byproduct inside the housing 110, which may adversely affect the process profile, the etch rate, and the uniformity of the etch rate.

Therefore, it is preferable that the time period for the etching gas to remain inside the housing 110 is from 1 second to 4 seconds.

According to the embodiment of the present invention, the plasma formed in the reaction space of the housing 110 includes the ions 21 and the radicals 22, and the wafer 10 may be etched by the synergy effect of the ions 21 and the radicals 22.

Further, according to the embodiment of the present invention, the plasma formed in the reaction space of the housing 110 includes the electrons, and an electron energy relaxation length (EERL) of the electron may be smaller than a diameter of the housing.

The plasma chamber 100 according to the embodiment of the present invention may be operated in a process region of local electron kinetics. The conventional etching process has been performed in a process region of nonlocal electron kinetics, where the electron energy relaxation length (EERL) is always larger than a diameter of a process chamber.

However, the plasma chamber 100 according to the embodiment of the present invention may operate in the process region of the local electron kinetics, where the electron energy relaxation length (EERL) is smaller than the diameter of the process chamber (i.e., the diameter of the housing 110).

This allows the plasma chamber 100 according to the embodiment of the present invention to have the plasma density at the edge of the housing 110 which is higher than the plasma density at the center of the housing 110, and also allows the etch rate of the plasma chamber 100 to be higher at the edge of the housing 110 than at the center of the housing 110.

In the conventional etching process, a problem of weak etching at the edge of the wafer (i.e., a low edge yield problem) may occur, and the plasma chamber 100 according to the embodiment of the present invention may prevent occurrence of the above problem as the etch rate at the edge of the housing 110 is formed higher than the etch rate at the center of the housing 110.

In addition, in the conventional etching process, in order to solve the problem of weak etching at the edge of the wafer (i.e., the low edge yield problem), an independent RF power is applied, or a heater, a lift device for preventing erosion of an edge ring, and the like are used.

However, the plasma chamber 100 according to the embodiment of the present invention may not use a separate device as the etch rate at the edge of the housing 110 is formed higher than the etch rate at the center of the housing 110, and thereby has the advantage of improving a yield while reducing a production cost.

The wafer etching method using the plasma chamber in the embodiment of the present invention relates to a method of etching the wafer 10 through the plasma chamber 100 according to the embodiment of the present invention as described above.

The plasma chamber 100 according to the embodiment of the present invention has been described in detail in the above description, and thus the detailed description of the plasma chamber 100 according to the embodiment of the present invention will be omitted hereinafter.

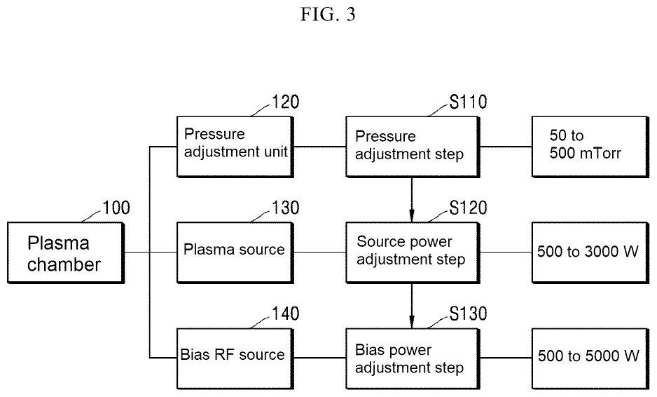

Referring to FIG. 3, the wafer etching method using the plasma chamber according to the embodiment of the present invention comprises a pressure adjustment step S110 and a source power adjustment step S120.

The pressure adjustment step S110 is a step of adjusting the pressure inside the housing 110 to be 50 to 500 mTorr via the pressure adjustment unit 120.

In the plasma chamber according to the embodiment of the present invention, if the pressure inside the housing 110 is less than 50 mTorr, the synergy effect of utilizing the ions 21 and the radicals 22 simultaneously is unlikely to be expected.

More specifically, if the pressure inside the housing 110 is less than 50 mTorr, the ion 21 dominated etching reaction may occur. In addition, when both the ions 21 and the radicals 22 are used simultaneously, there is a risk that the etch rate is reduced if the pressure inside the housing 110 is less than 50 mTorr.

If the pressure inside the housing 110 becomes greater than 500 mTorr, the reaction time may be shortened due to the excessive reactions between the particles, and rather, the etch rate may decrease.

Therefore, in the pressure adjustment step S110, it is preferable to regulate the pressure inside the housing 110 from 50 to 500 mTorr via the pressure adjustment unit 120. Further, according to another embodiment of the invention, in the pressure adjustment step S110, the pressure inside the housing 110 may be adjusted to be 100 to 150 mTorr, 200 to 500 mTorr, 300 to 500 mTorr, via the pressure adjustment unit 120.

The source power adjustment step S120 is a step of adjusting the source power of the plasma source 130 to be 500 to 3000 W through the plasma source 130.

It is preferable that the source power formed by the plasma source 130 is greater than 500 W because if the source power formed by the plasma source 130 is less than 500 W, the etch rate decreases.

As described above, since the pressure adjustment step S110 adjusts the pressure inside the housing 110 from 50 to 500 mTorr through the pressure adjustment unit 120, the pressure inside the housing 110 may be higher than the pressure in the conventional plasma chamber.

When the source power formed by the plasma source 130 is greater than 3000 W, the plasma density may become excessively high due to the relatively high internal pressure of the housing 110. If the plasma density becomes too high, the reaction time may be shortened due to excessive reactions between the particles, and rather, the etch rate may be reduced.

Therefore, in the power source adjustment step S120, it is preferable to adjust the source power of the plasma source 130 from 500 to 3000 W.

The pressure adjustment step S110 according to the embodiment of the present invention may adjust the pressure inside the housing 110 to the pressure equal to, or greater than, the resonance pressure, via the pressure adjustment unit 120.

Here, the resonance pressure may be a pressure at which the driving frequency of the plasma source 130 and the collision frequency between the particles inside the housing 110 are equalized.

For example, when the driving frequency of the plasma source 130 is 13.56 MHz, the resonance pressure at which the driving frequency of the plasma source 130 and the collision frequency between the particles inside the housing 110 are equalized, may be 52 mTorr, and when the driving frequency of the plasma source 130 is 27.12 MHz, the resonance pressure may be 104 mTorr.

In the pressure adjustment step S110 according to the embodiment of the present invention, the pressure adjustment unit 120 may adjust the pressure inside the housing 110 to a pressure equal to or greater than the resonance pressure determined by the driving frequency of the plasma source 130.

According to the embodiment of the present invention, the collision frequency between the particles inside the housing 110 may be determined as the product of the number of particles per unit volume and the rate constant for the collision reaction.

The plasma chamber according to the embodiment of the present invention may comprise the collision frequency analysis unit for analyzing the collision frequency between the particles occurring inside the housing 110. Using the collision frequency analysis unit, it is possible to derive the resonance pressure at which the collision frequency becomes equal to the driving frequency of the plasma source 130.

In the pressure adjustment step S110 according to an embodiment of the present invention, the pressure adjustment unit 120 may receive the data on the resonance pressure via the collision frequency analysis unit, which enables the pressure adjustment unit 120 to adjust the pressure inside the housing 110 to the pressure equal to or greater than the resonance pressure.

According to the embodiment of the present invention, it is preferable that the density of the plasma formed in the reaction space of the housing 110 is from 2E11 to 5E11 per cubic centimeter (cm⁻³).

If the density of the plasma formed in the reaction space of the housing 110 is less than 2E11 per cubic centimeter (cm⁻³), the targeted etch rate may not be obtained.

In contrast, if the density of the plasma formed in the reaction space of the housing 110 is greater than 5E11 per cubic centimeter (cm⁻³), the ions 21 and the radicals 22 are separated, and this may adversely affect the selectivity.

That is, the plasma chamber according to the embodiment of the present invention may form the density of the plasma formed in the reaction space of the housing 110 from 2E11 to 5E11 per cubic centimeter (cm⁻³) in order to improve the selectivity while improving the etch rate by simultaneously utilizing the ions 21 and the radicals 22.

The density of the plasma formed in the reaction space of the housing 110 according to the embodiment of the present invention may be adjusted by the power source adjustment step S120. The power source adjustment step S120 may form the plasma density inside the reaction space of the housing 110 to be 2E11 to 5E11 per cubic centimeter (cm⁻³) by adjusting the source power of the plasma source 130.

Referring to FIG. 3, the wafer etching method using the plasma chamber according to the embodiment of the present invention may further comprise a bias power adjustment step S130, which adjusts the bias power of the bias RF source 140 from 500 to 5000 W, via the bias RF source 140.

The bias RF source 140 may apply the bias to the base plate 111, thereby applying the bias to the plasma during the etching process.

The bias power directly affects the ions 21. If the bias power of the bias RF source 140 is less than 500 W, the activity of the ion 21 is restricted and instead the radical 22 is enabled to dominantly act, and thus the synergy effect of the ion 21 and the radical 22 may not be expected.

On the contrary, if the bias power of the bias RF source 140 is greater than 5000 W, the synergy effect of the ions 21 and the radicals 22 may not be expected as the ions become dominantly active.

Consequently, to derive the synergy effect through the ions 21 and the radicals 22, in the bias power adjustment step S130, the bias power of the bias RF source 140 may be adjusted from 500 to 5000 W.

Inside the housing 110 of the plasma chamber 100 according to the embodiment of the present invention, the etching gas for etching the wafer may be supplied. The etching gas supplied into the housing 110 may be discharged outside the housing 110 via the pump or the like after the reaction.

According to the embodiment of the present invention, the time period for which the etching gas remains or stays inside the housing 110 may be from 1 second to 4 seconds. Here, the time period for the etching gas to remain inside the housing 110 may be a time period from a point of time (or a moment) when the etching gas is supplied inside the housing 110 to a point of time when the etching gas is discharged outside the housing 110.

If the time period for the etching gas to reside inside the housing 110 is less than 1 second, the flow of the etching gas is not performed smoothly, and thus the reaction becomes insufficient.

On the contrary, if the time period for the etch gas to reside inside the housing 110 is greater than 4 seconds, the polymerization of the byproduct may cause the random accumulation of the byproduct inside the housing 110, which may adversely affect the process.

Therefore, it is preferable that the time period for the etch gas to remain inside the housing 110 is from 1 second to 4 seconds.

The pressure adjustment step S110, the source power adjustment step S120, and the bias power adjustment step S130 of the wafer etching method using the plasma chamber according to the embodiment of the present invention need not be performed sequentially, and each of these steps may be performed regardless of the order.

Further, the pressure adjustment step S110, the source power adjustment step S120, and the bias power adjustment step S130 of the wafer etching method using the plasma chamber according to the embodiment of the present invention may be performed simultaneously.

As such, the plasma chamber and the wafer etching method using the plasma chamber according to the embodiment of the present invention may adjust the pressure inside the housing 110 via the pressure adjustment unit 120, adjust the source power via the plasma source 130, and adjust the bias power via the bias RF source 140.

The plasma chamber and the wafer etching method using the plasma chamber according to the embodiment of the present invention may improve the selectivity while maintaining the high etch rate by generating the synergy effect due to the simultaneous utilization of the ions 21 and the radicals 22 and the resonance pressure effect due to the number of particle collisions, based on the adjustment of the pressure inside the housing 110, the source power, and the bias power.

According to the embodiment of the present invention, the plasma formed in the reaction space of the housing 110 includes the ions 21 and the radicals 22, and the wafer 10 may be etched by the synergy effect of the ions 21 and the radicals 22.

Further, according to the embodiment of the present invention, the plasma formed in the reaction space of the housing 110 includes the electrons, and the electron energy relaxation length (EERL) of the electron may be smaller than the diameter of the housing.

Different from the conventional etching process performed in the process region of the nonlocal electron kinetics, where the electron energy relaxation length (EERL) is larger than the diameter of the process chamber, the plasma chamber 100 according to the embodiment of the present invention may be operated in the process region of the local electron kinetics, where the electron energy relaxation length (EERL) is smaller than the diameter of the process chamber (i.e., the diameter of the housing 110).

This allows the plasma chamber 100 according to the embodiment of the present invention to have the plasma density at the edge of the housing 110 higher than at the center of the housing 110, and also allows the etch rate of the plasma chamber 100 to be higher at the edge of the housing 110 than at the center of the housing 110.

The plasma chamber 100 according to the embodiment of the present invention may solve the problem of weak etching at the edge of the wafer (i.e., the low edge yield problem) and may have the advantage of not using the separate device for solving such a problem, since the etch rate at the edge of the housing 110 is formed higher than the etch rate at the center of the housing 110.

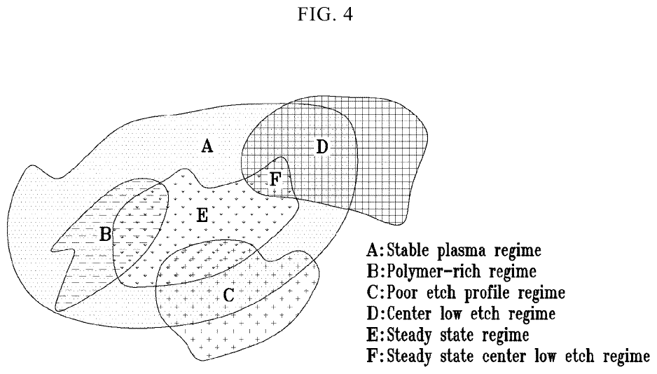

Referring to FIG. 4, the plasma chamber and the wafer etching method using the plasma chamber according to the embodiment of the present invention perform the etching by identifying a process region where the ions 21 and the radicals 22 can be utilized simultaneously.

In FIG. 4, a region A may be a stable plasma regime, that is a region where the plasma maintains stability that does not change over time. In FIG. 4, a region B is a region where the byproduct is generated too much, and a region C is a region where a plasma etch profile is distorted. Therefore, the regions B and C in FIG. 4 may not be the suitable process regions.

A region D in FIG. 4 is a region with a center low etch rate, and a region E region in FIG. 4 is a region where a process result does not change over time and has repeatability. To improve the repeatability over time while avoiding an edge yield loss of the wafer, a region that satisfies both the region D and the region E may be a desirable process region.

As a result, a region F of FIG. 4, which is included in the region A, but does not correspond to the regions B and C, and which simultaneously satisfies the regions D and E, may be the suitable process region.

The plasma chamber and the wafer etching method using the plasma chamber according to the embodiment of the present invention may adjust the conditions such as the pressure inside the housing 110, the source power, the bias power, and the like, in order to adjust the wafer etching process in the region F where the ions 21 and the radicals 22 can be utilized simultaneously.

In other words, the plasma chamber and the wafer etching method using the plasma chamber according to the embodiment of the present invention may set the process region as the region F in which the ions 21 and the radicals 22 can be utilized simultaneously, by adjusting the pressure inside the housing 110, the source power, and the bias power, and thereby may improve the selectivity while maintaining the high etch rate by generating the synergy effect of the ions 21 and the radicals 22.

As such, the plasma chamber and the wafer etching method using the plasma chamber according to the embodiment of the present invention may maintain the high etch rate by utilizing the ions 21 and the radicals 22 simultaneously.

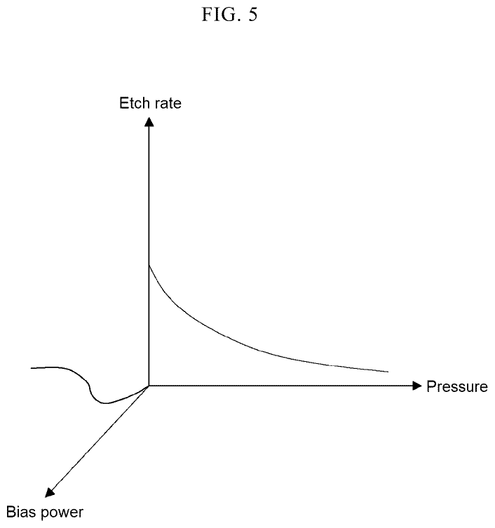

Referring to FIG. 5, when only the ions are utilized as in the conventional etching method, the etch rate tends to decrease when the pressure increases. Since the ions are independent of a temperature and mainly work well when the pressure is low, the bias power should be improved in order to increase the etch rate when etching is conducted using the ions. (Referring to FIG. 5, the etch rate may increase as the bias power increases.)

However, since the radicals increase exponentially over the temperature and may react actively to increase the etch rate as the pressure increases, if the ions and the radicals are utilized simultaneously as the embodiment of the present invention, the etch rate may be improved by increasing the pressure even without increasing the bias power.

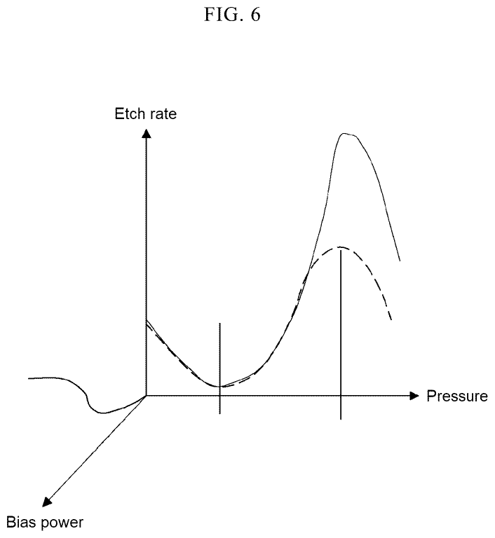

Particularly, referring to FIG. 6, it can be appreciated that when the ions and the radicals are utilized simultaneously like the embodiment of the present invention, the etch rate decreases up to a certain point as the pressure increases, and then, after a critical point, the etch rate increases as the pressure increases.

From the critical point where the etch rate increases as the pressure increases, the ions and the radicals generate the synergy effect to improve the etch rate. The plasma chamber and the wafer etching method using the plasma chamber according to the embodiment of the present invention therefore form the pressure of the housing 110 at or above the critical point (50 mTorr).

However, if the pressure is continuously increased, a surface reaction time may be too short so that the etch rate is not properly increased. Therefore, the plasma chamber and the wafer etching method using the plasma chamber according to the embodiment of the present invention set the pressure of the housing 110 from 50 mTorr to 500 mTorr.

In a graph of etch rate-pressure of FIG. 6, a dashed line is a graph when the bias power thereof is reduced than a solid line. Referring to FIG. 6, by adjusting the bias power to a suitable value, the high etch rate may be obtained at the pressure at or above the critical point.

For this reason, the plasma chamber and the wafer etching method using the plasma chamber according to the embodiment of the present invention may set the bias power from 500 to 5000 W, while setting the source power from 500 to 3000 W.

In other words, the plasma chamber and the wafer etching method using the plasma chamber according to the embodiment of the present invention may form the pressure in which the ions and the radicals can generate the synergy effect to improve the etch rate, and may realize the process region having an optimal etch rate by adjusting the bias power and the source power.

The plasma chamber according to the embodiment of the present invention may comprise a control unit for controlling the operations of the pressure adjustment unit 120, the plasma source 130, the RF power generator 132, and the bias RF source 140.

According to the embodiment of the present invention, the pressure adjustment unit 120, the plasma source 130, the RF power generator 132, and the bias RF source 140 may form the condition in which the ions 21 and the radicals 22 can be utilized simultaneously, while their operations are regulated via the control unit.

Further, the pressure adjustment step S110, the source power adjustment step S120, and the bias power adjustment step S130 of the wafer etching method using the plasma chamber according to the embodiment of the present invention may be performed while being controlled through the control unit.

The plasma chamber and the wafer etching method using the plasma chamber according to the above-described embodiments of the present invention have the following advantages.

The plasma chamber and the wafer etching method using the plasma chamber according to the embodiment of the present invention have the advantage that as the pressure inside the chamber is formed to be the pressure relatively higher than the pressure of the conventional chamber, the etching of the wafer may be performed by simultaneously utilizing the ions and the radicals, and thereby the PR selectivity may be improved while a high etch rate is maintained.

The plasma chamber and the wafer etching method using the plasma chamber according to the embodiment of the present invention may be operated in a pressure range (i.e., 50 to 500 mTorr) to which the local electron kinetics is applied, and in this case, the etch rate at the edge may be higher than the etch rate at the center.

This allows the plasma chamber and the wafer etching method using the plasma chamber according to the embodiment of the present invention to have the advantage of avoiding a decrease in uniformity at the edge of the wafer.

The plasma chamber and the wafer etching method using the plasma chamber according to the embodiment of the present invention are suitable for a high aspect ratio etch (HARC) process, and may obtain the high etch rate and the high selectivity at a low power in other processes.

The plasma chamber and the wafer etching method using the plasma chamber according to the embodiment of the present invention have been described focusing on the etching process, but are not limited thereto. The plasma chamber and the wafer etching method using the plasma chamber according to the embodiment of the present invention may be applied to processes such as deposition, ashing, PR stripping, doping, and the like, in addition to the etching process.

The plasma chamber and the wafer etching method using the plasma chamber according to the embodiment of the present invention may be applied to the etching process that requires the etch rate or the deposition process, but are not limited thereto, and may of course be applied to various processes that simultaneously require the high etch rate and the selectivity improvement with low power.

The plasma chamber and the wafer etching method using the plasma chamber according to the embodiment of the present invention may be used by improving the inductively coupled plasma (ICP), but are not limited thereto, and may also be utilized for various types of plasma.

The present invention has thus been described with reference to the embodiments shown in the drawings, but this is exemplary only, and those having ordinary skill in the art would appreciate that various modifications and variations of the embodiments are available therefrom. Accordingly, the true scope of technical protection of the present invention should be determined by the technical concept of the appended patent claims.

1. A plasma chamber configured to form plasma, the plasma chamber comprising:
a housing configured to have a reaction space therein, in order to etch a wafer through the plasma;
a base plate provided inside the housing and configured to allow the wafer to be seated thereon; and
a pressure adjustment unit configured to adjust a pressure inside the housing,
wherein the pressure adjustment unit is configured to adjust the pressure inside the housing from 50 to 500 mTorr.

2. The plasma chamber of claim 1, further comprising a plasma source provided on an upper part of the housing and configured to form the plasma inside the housing, wherein a source power of the plasma source is from 500 to 3000 W.

3. The plasma chamber of claim 2, wherein the pressure adjustment unit is configured to adjust the pressure inside the housing to a pressure equal to or greater than a resonance pressure, at which a driving frequency of the plasma source and a collision frequency between particles inside the housing are equalized.

4. The plasma chamber of claim 1, wherein etching gas is supplied inside the housing and the etching gas supplied into the housing is discharged outside the housing after reaction, and
wherein a time period for which the etching gas remains inside the housing is from 1 second to 4 seconds.

5. The plasma chamber of claim 1, wherein a density of the plasma formed in the reaction space of the housing is from 2E11 to 5E11 per cubic centimeter (cm⁻³).

6. The plasma chamber of claim 1, further comprising a bias RF source connected to the base plate and configured to apply a bias to the base plate,
wherein a bias power of the bias RF source is from 500 to 5000 W.

7. The plasma chamber of claim 1, wherein the plasma formed in the reaction space of the housing includes ions and radicals, and
wherein the wafer is etched by synergy effect of the ions and the radicals.

8. A wafer etching method using a plasma chamber, which includes a housing configured to have a reaction space therein in order to etch a wafer through plasma, a base plate provided inside the housing and configured to allow the wafer to be seated thereon, a pressure adjustment unit configured to adjust a pressure inside the housing, and a plasma source provided on an upper part of the housing and configured to form the plasma inside the housing, the method comprising:
a pressure adjustment step of adjusting the pressure inside the housing to be 50 to 500 m Torr though the pressure adjustment unit; and
a source power adjustment step of adjusting a source power of the plasma source to be 500 to 3000 W through the plasma source.

9. The wafer etching method of claim 8, wherein in the pressure adjustment step, the pressure inside the housing is adjusted to a pressure equal to or greater than a resonance pressure, at which a driving frequency of the plasma source and a collision frequency between particles inside the housing are equalized, through the pressure adjustment unit.

10. The wafer etching method of claim 8, wherein etching gas is supplied inside the housing and the etching gas supplied into the housing is discharged outside the housing after reaction, and
wherein a time period for which the etching gas remains inside the housing is from 1 second to 4 seconds.

11. The wafer etching method of claim 8, wherein a density of the plasma formed in the reaction space of the housing is from 2E11 to 5E11 per cubic centimeter (cm⁻³).

12. The wafer etching method of claim 8, wherein the plasma chamber includes a bias RF source connected to the base plate and configured to apply a bias to the base plate, and further comprising a bias power adjustment step of adjusting a bias power of the bias RF source to be 500 to 5000 W through the bias RF source.

13. The wafer etching method of claim 8, wherein the plasma formed in the reaction space of the housing includes ions and radicals, and
wherein the wafer is etched by synergy effect of the ions and the radicals.
